(19) United States
(12) Patent Application Publication
(10) Pub. No.: US 2005/0266902 A1
(43) Pub. Date: Dec. 1, 2005

(54) Multiple transmission channel wireless communication systems

(76) Inventors: Bhavin S. Khatri, London (GB); Kevin R. Boyle, Horsham (GB)

Correspondence Address: PHILIPS INTELLECTUAL PROPERTY & STANDARDS, P.O. BOX 3001, BRIARCLIFF MANOR, NY, 10510, US

(21) Appl. No.: 10/520,309

(22) PCT Filed: Jul. 8, 2003
(86) PCT No.: PCT/IB03/03010

§ 371 Date: Jan. 5, 2005

(30) Foreign Application Priority Data
Jul. 11, 2002 (GB) 0216060.4

(51) Int. Cl. H04B 1/02; H03C 7/02; H04B 7/02; H04B 1/00

(52) U.S. Cl. 455/575.7; 455/101; 455/272; 455/132

(57) ABSTRACT

A multiple transmission channel wireless communication system such as MIMO system, comprises a transmitting station and at least one receiving station, at least one of said stations having an antenna system comprising a plurality of spaced apart antenna elements (16A, 16B), each antenna element comprising a sub-array of at least 2 antennas (20A, 20B) separated by less than half the wavelength of the frequency of interest The antennas of each of the antenna elements may be controllable to give directional propagation or reception.

The present invention relates to improvements in or relating to multiple transmission channel wireless communication systems, such as MIMO (Multiple Input Multiple Output) and spatial diversity wireless communication systems, and particularly, but not exclusively, to an antenna system for use in such communication systems.

Recent developments in Information Theory, for example (1) Forschini G. J, Gans M. J, “On limits of wireless communications in a fading environment when using multiple antennas”, Wireless-Personal-Communications (Netherlands), vol.6, no.3, pp311 to 335, March 1998 and (2) Telatar I E, “Capacity of multi-antenna Gaussian Channels,” Tech. Rep. #BL0112170-950615-07TM AT&T Bell Laboratories, 1995, have shown that unprecedented capacities may be attainable in wireless communications systems by the use of multiple antennas at both the transmitter and the receiver. The capacity increase arises, since multiple antennas at both ends can take advantage of the fact that signal energy departs and arrives from many different directions, allowing the spatial separation of antennas to distinguish these paths. Thus, multiple signals or substreams can be sent simultaneously and decoded. One such scheme to take advantage of this is known as BLAST (Bell Labs Layered Space Time) details of which are disclosed in (3) Foschini G J, “Layered space-time architecture for wireless communication in a fading environment when using multi-element antennas”, Bell-Labs-Technical-Journal (USA), vol.1, no.2, pp41 to 59, Autumn 1996 and (4) Wolniansky P W, Forschini G J, Golden G D, Valenzuela R A, “V-BLAST: an architecture for realising very high data rates over the rich-scattering wireless channel”, 1998 URSI International Symposium on Signal, Systems, and Electronics, Conference Proceedings, Pisa, Italy, 29 Sep. to 2 Oct. 1998. In BLAST different substreams are sent to different antennas at the transmitter. The substreams are decoded at a receiver through a measurement of the MIMO channel which allows a process of nulling substreams and subtracting the effect of already detected substreams. This method requires knowledge of the channel at the receiver.

An alternative to this method is disclosed in unpublished PCT application IB 02/00029 (Applicant's reference PHGB 010012) in which the substreams are transmitted in different directions and are received from different directions, more particularly from those directions where the most power is coming from, as determined by a measurement of angles of arrival of multipath at the transmitter and the receiver. This method requires knowledge of the channel at the transmitter (angles of departure to scatterers), although the receiver could be used with a transmitter which has no knowledge, for example a BLAST transmitter.

Both these methods require arrays of antennas and have a fundamental requirement on the antenna spacing, namely the spacing between adjacent antennas should be of the order of half a wavelength (λ/2). For BLAST, this is because when it is assumed that rays arrive on average uniformly in azimuth, the distance another antenna should be spaced is a bit less than λ/2, or preferably more. Similarly, in order to unambiguously specify a beam pattern, a spacing of λ/2 or less is needed. However there appears to be a fundamental limitation on the number of antennas that can be packed onto a given area for a given wavelength and in consequence unambiguously specifying a beam pattern is difficult to implement. Additionally each antenna requires a respective processor for recovering a base band signal from the RF signal received by the antennas simultaneously. Processing separately a lot of RF signals is relatively difficult and expensive.

An object of the present invention is to increase the number of antennas which can be packed into a given area without adversely affecting the operation of the system.

According to one aspect of the present invention there is provided a multiple transmission channel wireless communication system comprising a transmitting station and at least one receiving station, at least one of said stations having an antenna system comprising a plurality of spaced apart antenna elements, each antenna element comprising a sub-array of at least 2 antennas separated by less than λ/2 of the frequency of interest.

According to a second aspect of the present invention there is provided an antenna system for use in a multiple transmission channel wireless communication system, the antenna system comprising a plurality of spaced apart antenna elements, each antenna element comprising a sub-array of at least 2 antennas separated by less than λ/2 of the frequency of interest.

The present invention is based on recognition of the fact that each of the antenna elements of a large antenna array can be replaced by a sub-array of closely spaced antennas and by using RF networks to pre-process the RF signals received by the antennas of the sub-array, the number of base band processors required is reduced compared to having one processor for each is antenna. A MIMO system (or spatial diversity system) constructed with an array of say N elements with each element comprising n antennas is capable of forming in general at least nN directional beams. At one extreme for a MIMO system, if all n beams of each of the N elements are used, then a nN×nN MIMO system would be created in the space normally taken up by a N×N system. Each of the branches would be decorrelated through a combination of pattern (amplitude and phase) and spatial diversity. The spatial diversity relies on the spatial separation of elements so that two identical beam patterns that are spatially separated are decorrelated to some degree. At the other extreme the best of the n beams for each of the N elements could be selected to give a N×N system.

It is known to employ spatial diversity employing two antenna elements in communication systems, such as DECT (Digitally Enhanced Cordless Telecommunications). Each of the antenna elements is designed to be omnidirectional and independent from the other antenna element. In order to avoid having to separate the antenna elements by a large distance and, optionally detuning the unused antenna element, Patent Specification WO 01/71843 (Applicant's reference PHGB 000033) discloses an antenna diversity arrangement in which a plurality of antennas are fed with a signal of suitable amplitude and phase to enable the generation of a plurality of antenna beams, the correlation coefficient between-any pair of beams being substantially zero. The resultant antenna diversity arrangement can comprise pairs of antennas arbitrarily close to one another with near zero correlation between any pair of antenna beams, thereby providing a compact and effective arrangement. There is no disclosure of such arrangement in a MIMO system such as BLAST.

The present invention will now be described, by way of example, with reference to the accompanying drawings, wherein:

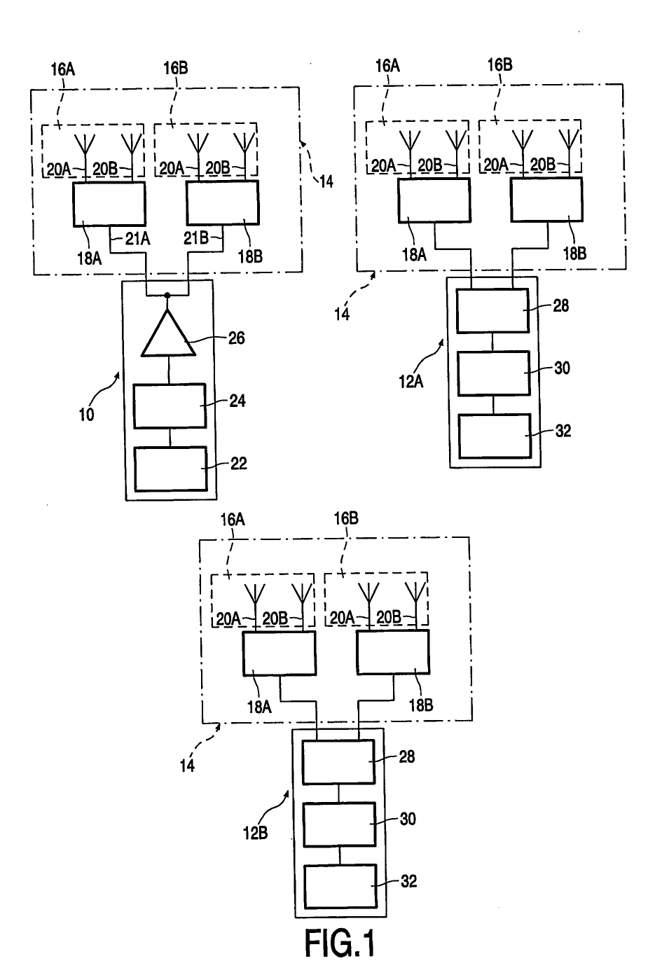

FIG. 1 is a block schematic diagram of a MIMO system,

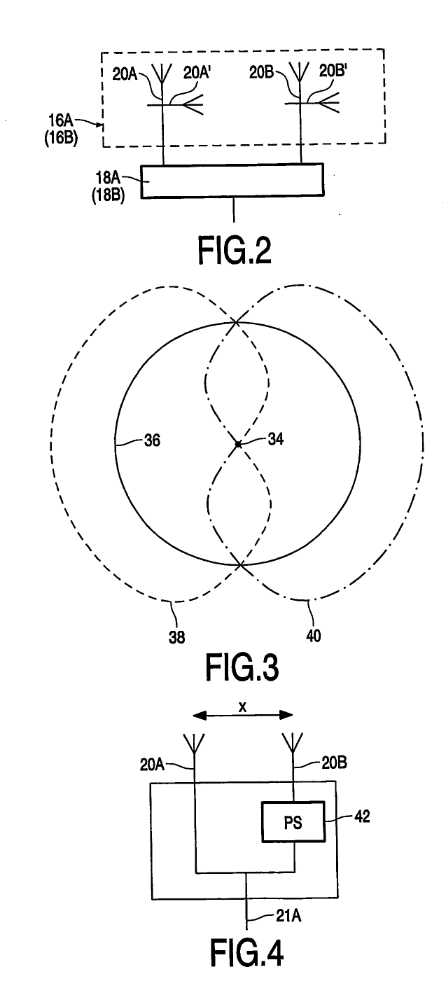

FIG. 2 is a sketch of an antenna element comprising two pairs of orthogonally arranged antennas,

FIG. 3 is a diagram illustrating the directional coverage of two directed beams compared with an omnidirectional beam,

FIG. 4 is a block schematic diagram of an antenna diversity arrangement,

FIG. 5 is a sketch of a high-density MIMO system having directional antenna elements,

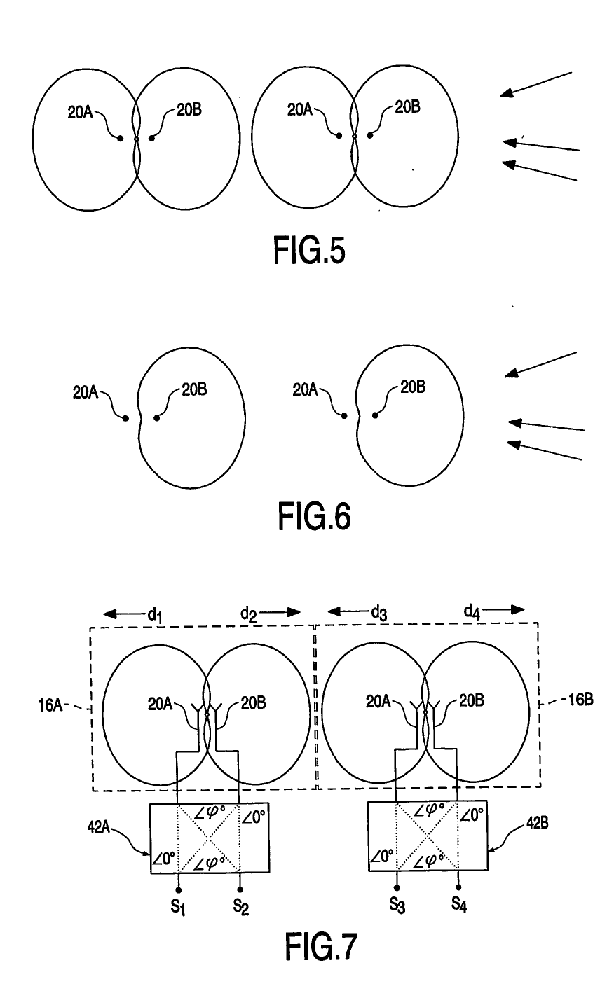

FIG. 6 is a sketch of a high-density MIMO system in which an element can be switched between one of two directions.

FIG. 7 is an embodiment of an antenna arrangement in which sub-arrays of two antenna elements are fed using a directional coupler, and

FIGS. 8 to 10 are sketches of the antenna arrangement for a switched MIMO system.

In the drawings the same reference numerals have been used to indicate corresponding features.

Referring to FIG. 1 the MIMO system comprises a radio transmitter (Tx) 10 and two radio receivers (Rx) 12A, 12B. As mentioned in the preamble it is customary for the Tx 10 and the Rx 12A, 12B to have multiple antenna elements because signal energy relating to multiple signals or substreams depart and arrive from many different directions. Optionally knowledge of the angles of departure and arrival are used to select the beam directions from which signals having the most power are coming from. For simplicity of illustration the Tx 10 and the Rx 12A, 12B each have a similar antenna system 14. The antenna system 14 comprises at least two antenna elements 16A, 16B spatially separated by substantially half a wavelength (λ/2) of the desired frequency or centre frequency. Each of the antenna elements 16A, 16B comprises a RF network 18A, 18B to each of which two antennas 20A, 20B are connected. The antennas 20A, 20B of each of the antenna elements 16A, 16B are spaced apart by less than λ/2, typically λ/4 or 90° for oppositely directed beams. The electrical spacing may be arbitrary for decorrelated beams, for example 125°.

In the case of the Tx 10, data is encoded by an encoder 22 and the encoded signal is modulated on a carrier by a modulator 24. The modulated signal is supplied to a power amplifier 26 having outputs coupled respectively by lines 21A, 21B to the respective RF network 18A, 18B. the feed arrangements 18A, 18B may control their respective pairs of antennas 20A, 20B such that they propagate signals in a predetermined direction or directions.

In each of the receivers Rx 12A, 12B, the respective RF networks 18A, 18B are coupled to an RF stage 28, an output of which is coupled to a demodulator 30. A decoder 32 is coupled to an output of the demodulator 30. The RF networks 18A, 18B serve to process RF signals from both the antennas 20A, 20B thereby reducing the number of receivers and the base band processors compared to having one receiver and base band processor per antenna. In addition these RF networks manage in a beneficial way RF interaction problems which would otherwise arise between close proximity antennas. In a further refinement the receiver RF networks 18A, 18B may control their respective antennas such that signals are detected from those directions from which the most power is received.

FIG. 2 illustrates a variant of the antenna elements 16A, 16B shown in FIG. 1. In this variant each antenna of the antenna element 16A, (16B), respectively comprises a pair of orthogonally arranged antennas 20A, 20A′ and 20B, 20B′ providing orthogonal polarisation.

In order to facilitate an understanding of how the RF networks may be used to control the direction of transmission and/or reception reference is made to FIG. 3 which shows an example of directional coverage from a two element antenna array as shown in FIG. 4. A transmitter 34 having a diversity arrangement is able to transmit and receive by way of an omnidirectional beam 36, a first directional beam 38 shown in broken lines and a second directional beam 40 shown in chain dashed lines.

Referring to FIG. 4 it is assumed that the antenna elements 20A, 20B are located on a single axis. In a first transmission mode, the antenna element 20A is considered as the reference and the feed to the antenna element 20B has its amplitude and phase adjusted by a stage 42, causing a directional beam to be formed in a particular direction. In a second transmission mode the relative amplitudes and phases are reversed, thereby causing a directional beam in the opposite direction. The stage 42 can adjust the phase of the signal by up to ±180°. In view of the reciprocal nature of antenna systems the same explanation applies to making the receiving antennas directional.

FIG. 5 illustrates pairs of antenna elements arranged sufficiently close together that their mutual couplings become increasingly significant and has the effect of causing re-radiation from adjacent antennas. This causes the radiation pattern for each antenna to become directional in the presence of the other, as opposed to omnidirectional when there is no mutual coupling. Increased directionality means that in general, each antenna will tend to sample different multipath or different weighted combinations of the same multipath so that correlation is decreased.

In accordance with the present invention an antenna element comprises an array formed from two or more closely spaced antennas and the arrays are combined to form a larger antenna system. A MIMO system (or spatial diversity system) is constructed with an array of say N antenna elements, each element comprising n antennas capable of forming in general n directional beams. At one extreme for a MIMO system, if use is made of all n beams of each of the N antenna systems, then a nN×nN MIMO system would be created in the space normally taken up by a N×N system. Each of the branches would be decorrelated through a combination of pattern (amplitude and phase) and spatial diversity. The spatial diversity relies on the spatial separation of the antennas comprising each of the antenna elements so that two identical beam patterns that are spatially separated are decorrelated to some degree. At the other extreme the best of the n beams for each of the N elements could be selected to give a N×N system.

A possible drawback of having a high density MIMO system of a type as shown in FIG. 5 which could be a receiver for a 4×4 MIMO system (or a 1×4 diversity receiver) is that it is susceptible to the instantaneous angles of arrival having a narrow angular spread which may create a problem of very unequal powers being received across its beams and have the effect that some beams may not receive any power from any of the substreams. This would be catastrophic from a MIMO viewpoint, since it would then be impossible to reliably decode the substreams, as the number of received samples of the substreams (antennas or different beam patterns) will be less than the number of substreams (that is the number of independent equations is less than the number of unknowns).

This is less likely to occur with the arrangement shown in FIG. 6 where each sub-array selects one of many possible directions so that it can choose a beam direction that is sure to receive a certain amount of power. In the case of the example shown in FIG. 6 both beams have been selected to point in the direction from which the most multipath is coming. In this instance it is the same direction. Their spatial separation is the mechanism for decorrelating the two branches, although the amount of decorrelation may or may not be as good as spatial diversity with omnidirectional antennas, for the same element spacing. However, there will be roughly an extra 3 dB gain in the end-fire direction for both branches, which may counteract any decrease in capacity due to extra correlation.

The example shown in FIG. 6 is an extreme example because it assumes that no power is coming from the opposite direction and therefore it is better to point both beams in the same direction. If this assumption is not made then it may be better to select a better switching algorithm than one which selects the strongest direction since correlation between the branches may be the most important factor. So even though there may be less power from the opposite direction, by selecting that direction the overall correlation will be less.This would need to be trade off against the fact there is less overall power and a difference in power across the branches.

Comparing the arrangements shown in FIGS. 5 and 6, there is a trade-off between the high density method (FIG. 5) of using all possible modes to give a nN×nN MIMO system in the space of a N×N system, but there could be an issue with reliability, and the switched architecture (FIG. 6) which gives a N×N system, but with the possibility of increased reliability and capacity.

Referring to FIG. 7, the high density MIMO system comprises arrays 16A, 16B of antenna elements respectively formed by the antennas 20A, 20B which are phased using RF phase shifters or using phase shifts in the digital domain. FIG. 7 illustrates a 4×4 MIMO transmitter in which hybrid couplers 42A, 42B are used to phase pairs of closely spaced antennas 20A, 20B. The hybrid couplers 42A, 42B are supplied with pairs of signal voltages s₁,s₂ and s₃,s₄, respectively. When the signal voltages s₁ and s₃ are high relative to the signal voltages s₂ and s₄, the antenna elements are directional in the directions d₁ and d₃. In the converse situation the antenna elements 16S, 16B are directional in the directions d₂ and d₄.

At the receiver the four ports of the hybrid coupler 42A or 42B would be the four branches of the MIMO receiver. This principle can be extended for any N, with n=2. A possible problem with this arrangement would come with finding the appropriate matching between source, hybrid coupler and antenna, since the impedance between the different ports of the coupler will vary with different phase shifts. An alternative method of applying phase shifts is to use digital beam forming techniques, where problems of impedance matching of arrays is largely negated. It should be noted that in these MIMO cases it is necessary to have as many RF transmitters and receivers as there are substreams.

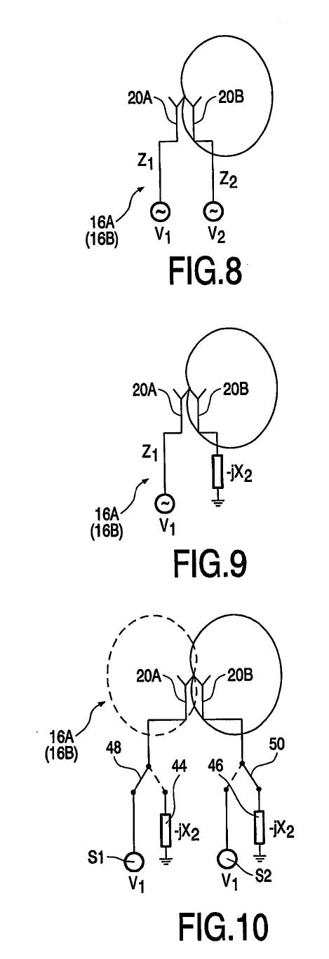

FIG. 8 shows an embodiment of part of a switched MIMO system which comprises one of two antenna elements 16A (16B) with each of the antenna elements comprising antennas 20A, 20B. In this embodiment each antenna element 16A (16B) is controlled to select one of the two possible beams, so that there are just two substreams transmitted or two samples of substreams received. Switched parasitics are used to switch the antennas 20A, 20B of each antenna element. In FIG. 8 a directional beam is formed as shown using complex voltages V₁ and V₂ fed respectively to the antennas 20A, 20B. The resultant complex impedances of the antennas are Z₁ and Z₂, respectively. The same beam pattern can also be produced by replacing the source V₂ with a pure reactance −jX₂, which is the imaginary part of the impedance of the antenna 20B. Using this reactance means the mutual interactions will produce very nearly the correct feed voltages in which the source V₂ is replaced by a pure reactance −jX₂. This technique works best when the resistive part of the impedance is small. This is shown in FIG. 9.

In order to produce a beam in the opposite direction, the voltages would need to be swapped and thus the impedances of the antennas will also be swapped. The antenna 20A would be terminated with an impedance −jX₂ and the antenna 20B fed with a voltage V₁.

FIG. 10 shows a combination of these possibilities using a switching architecture with a single antenna element 16A comprising the antennas 20A, 20B. Two sources s₁, s₂ and two impedances 44,46, shown as identical pure reactances −jX₂, are provided and a first changeover switch 48 connects either the source S1 or the impedance 44 to the antenna 20A and a second changeover switch 50 connects either the impedance 46 or the source S2 to the antenna 20B. With the switches 48, 50 in the positions shown the directional lobe is as shown in full lines and with these switches in their opposite positions, as shown broken lines, the directional lobe is as shown in broken lines.

The improved antenna system may be used with transmitters and receivers operating in accordance with various standards, such as UMTS, HiperLan/2, IEEE 802.11A & B. It may be used to improve the capacity of mobile and wireless LANs by providing higher data rates, lower power consumption or lower bandwidth wireless communications devices.

In the present specification and claims the word “a” or “an” preceding an element does not exclude the presence of a plurality of such elements. Further, the word “comprising” does not exclude the presence of other elements or steps than those listed.

From reading the present disclosure, other modifications will be apparent to persons skilled in the art. Such modifications may involve other features which are already known in the design, manufacture and use of multiple transmission channel wireless communication systems and component parts therefor and which may be used instead of or in addition to features already described herein. Although claims have been formulated in this application to particular combinations of features, it should be understood that the scope of the disclosure of the present application also includes any novel feature or any novel combination of features disclosed herein either explicitly or implicitly or any generalisation thereof, whether or not it relates to the same invention as presently claimed in any claim and whether or not it mitigates any or all of the same technical problems as does the present invention. The applicants hereby give notice that new claims may be formulated to such features and/or combinations of such features during the prosecution of the present application or of any further application derived therefrom.

1. A multiple transmission channel wireless communication system comprising a transmitting station (10) and at least one receiving station (12), at least one of said stations having an antenna system (14) comprising a plurality of spaced apart antenna elements (16A,B), each antenna element comprising a sub-array of at least 2 antennas (20A,B) separated by less than λ/2 of the frequency of interest.

2. A system as claimed in claim 1, characterised in that the antennas (20A,B) of a sub-array are coupled to an RF network (18A,B) for processing signals received by the antennas.

3. A system as claimed in claim 1 or 2, characterised in that the antennas (20A,B) of each sub-array are spaced apart by less than λ/4.

4. A system as claimed in claim 1, characterised in that a hybrid coupler (42A,B) couples together the antennas of each sub-array.

5. A system as claimed in claim 1 or 2, characterised in that the antennas (20A,B) of a sub-array are switchable to achieve directional propagation or reception.

6. A system as claimed in claim 1, characterised in that the antenna systems (14) form multiple orthogonal antenna beam patterns.

7. A system as claimed in claim 1 or 2, characterised in that the sub-arrays comprise antennas (20) arranged to give orthogonal polarisation.

8. An antenna system for use in a multiple transmission channel wireless communication system, the antenna system comprising a plurality of spaced apart antenna elements (16A,B), each antenna element comprising a sub-array of at least 2 antennas (20A,B) separated by less than λ/2 of the frequency of interest.

9. An antenna system as claimed in claim 8, characterised in that the antennas (20A,B) of a sub-array are coupled to an RF network (18A,B) for processing signals received by the antennas.

10. An antenna system as claimed in claim 8 or 9, characterised in that the antennas (20A,B) of each sub-array are spaced apart by less than λ/4.

11. An antenna system as claimed in claim 8, characterised in that a hybrid coupler (42A,B) couples together the antennas of each subarray.

12. An antenna system as claimed in claim 8 or 9, characterised in is that the antennas (20A,B) of a sub-array are switchable to achieve directional propagation or reception.

13. An antenna system as claimed in claim 8 or 9, characterised in that the antenna systems (14) form multiple orthogonal antenna beam patterns.

14. An antenna system as claimed in claim 8 or 9, characterised in that the sub-arrays comprise antennas (20) arranged to give orthogonal polarisation.
